(19) United States
(12) Patent Application Publication
(10) Pub. No.: US 2026/0186058 A1
(43) Pub. Date: Jul. 2, 2026

(54) METHOD FOR FINDING PATTERNS FOR DIAGNOSTIC ANALYSIS

(71) Applicant: Fluence Energy, LLC, Arlington, VA (US)

(72) Inventors: Thomas Jeffrey Winter, Decatur, GA (US); Brett Lance Galura, Vienna, VA (US)

(73) Assignee: Fluence Energy, LLC, Arlington, VA (US)

(21) Appl. No.: 18/867,636

(22) PCT Filed: Sep. 27, 2024
(86) PCT No.: PCT/US2024/048769

§ 371 Date: Nov. 20, 2024

Related U.S. Application Data
(60) Provisional application No. 63/541,145, filed on Sep. 28, 2023.

(51) Int. Cl. G01R 31/367; G01R 31/392

(52) U.S. Cl. CPC G01R 31/367; G01R 31/392

(57) ABSTRACT

A system includes an energy storage system including a plurality of energy storage nodes, each of which includes a battery storage element, a memory, a processor coupled to the memory and the plurality of energy storage nodes, and programming in the memory. Execution of the programming by the processor characterizes blocks of historical operating data from the energy storage nodes, creates summary parameters for the blocks of historical operating data, evaluates each of the summary parameters against selection criteria, and feeds selected operating data as suitable input data to a diagnostic analysis protocol for the energy storage system based on the evaluation of the summary parameters against the selection criteria.

### CROSS-REFERENCE TO RELATED APPLICATIONS

This application claims priority to U.S. Patent Application No. 63/541,145 filed on Sep. 28, 2023, titled “Method for Finding Patterns for Diagnostic Analysis,” the content of which is hereby incorporated by reference in its entirety.

### TECHNICAL FIELD

The present subject matter relates to examples of an analytics system design and embedded methods which search the operational data of a battery energy storage system to determine suitable data for performance improving analytics.

### BACKGROUND

Battery energy storage systems, compound energy storage systems, as well as energy provisioning systems are systems with a large number of complex interrelated parts, all of which need to be operating and configured optimally in order to maximize the productivity of the energy provisioning system. To ensure that the energy provisioning system, and its components and sub-components are functioning nominally, analytical tools are heavily relied upon to make assessments and report issues based on sensor data and electrical flows through the energy provisioning system.

Analytic tools, no matter whether they are traditional in nature or based on machine learning or artificial intelligence algorithms, require suitable data as input to generate a meaningful output. Data scientists refer to noisy data being fed to analytical tools which can then produce inaccurate or unactionable data as “garbage in, garbage out.” Generating suitable input data is a problem in contemporary energy provisioning systems. Data that comes off an operating energy provisioning system or a component, or sub-component of an energy provisioning system, when randomly sampled may not have the right operating characteristic (e.g., too high or too low power), may not be in the right operating range (e.g., wrong state of charge), may not have the right sequence (e.g., need one step before another), or may have other incorrect operating characteristics.

There are several strategies the energy provisioning systems currently seek to solve this problem. First, significant time and effort may be expended during algorithm development in accommodating data sets which have undesirable characteristics or defects. This strategy takes the form of additional development expense and slower time to market and, in some cases, results in less effective or maintainable code. Second, there is the strategic concept of the “diagnostic profile”. This strategy involves running the energy provisioning system (or a sub-component) in a certain way to generate the characteristic data needed by the algorithm to work. However, operating the energy provisioning system or its sub-components under this “diagnostic profile” nearly always conflicts with the way the energy provisioning system or sub-component would tend to operate otherwise. This strategy, therefore, results in a cost being incurred—the energy provisioning system or its sub-components must be run in a way which is suboptimal for its market application, reducing the revenue or increasing the cost of the energy provisioning system owner. In some cases, the energy provisioning system or its sub-components may need to be entirely removed from service to run the “diagnostic profile.” This reduces the availability of the energy provisioning system or sub-component, which, in addition to affecting the asset owner, may come with consequences for the service team that is charged with keeping the energy provisioning system its sub-component online and ready to operate.

Hence, there is a need for systems directed to analytics of an energy storage system which find patterns in operating data to create suitable data as an input (i.e., suitable input data) for a diagnostics analysis tool.

### SUMMARY

In a first example, an energy storage system 101 includes a plurality of energy storage nodes 105A-N, each of which includes a battery storage element 106A-N, a memory 313, 353, a processor 312, 352 coupled to the memory 313, 353 and the plurality of energy storage nodes 105A-N, and suitability analytics control programming 330A-B in the memory 313, 353. Execution of the suitability analytics control programming 330A-B by the processor 312, 352 configures the energy storage system 101 to characterize blocks 511A-N of historical operating data 505 from the plurality of energy storage nodes 105A-N, create summary parameters for the blocks 511A-N of historical operating data 505, evaluate each of the summary parameters against selection criteria, and feed selected operating data 515 as suitable input data to a diagnostic analysis protocol 350A-B for the energy storage system 101 based on the evaluation of the summary parameters against the selection criteria.

In a second example, a method includes characterizing blocks of historical operating data 505 from a plurality of energy storage nodes 105A-N of an energy storage system 101, creating summary parameters for the blocks 511A-N of historical operating data 505, evaluating each of the summary parameters against selection criteria, and feeding selected operating data 515 as suitable input data to a diagnostic analysis protocol 350A-B for the energy storage system 101 based on the evaluation of the summary parameters against the selection criteria.

In a third example, a non-transitory computer-readable medium 313, 353 includes suitability analytics control programming 330A. Execution of the suitability analytics control programming 330A-B by one or more processors 312, 252 configures one or more computing devices to: characterize blocks 511A-N of historical operating data 505 from a plurality of energy storage nodes 105A-N of an energy storage system 101; create summary parameters for the blocks 511A-N of historical operating data 505; evaluate each of the summary parameters against selection criteria; and feed selected operating data 515 as suitable input data to a diagnostic analysis protocol 350A-B for the energy storage system 101 based on the evaluation of the summary parameters against the selection criteria.

Additional objects, advantages and novel features of the examples will be set forth in part in the description which follows, and in part will become apparent to those skilled in the art upon examination of the following and the accompanying drawings or may be learned by production or operation of the examples. The objects and advantages of the present subject matter may be realized and attained by means of the methodologies, instrumentalities and combinations particularly pointed out in the appended claims.

### BRIEF DESCRIPTION OF THE DRAWINGS

The drawing figures depict one or more implementations in accordance with the present concepts, by way of example only, not by way of limitations. In the figures, like reference numerals refer to the same or similar elements.

FIG. 1 depicts a system that includes an energy storage system, an energy system, and an electrical application, according to embodiments of the present disclosure.

FIG. 2 illustrates a first energy storage node of a plurality of energy storage nodes of the energy storage system of FIG. 1 coupled to the electrical application.

FIG. 3 is a cutaway view of the first energy storage node of the plurality of energy storage nodes and shows details of a plurality of battery storage elements.

FIG. 4 is a high-level functional block diagram of the energy storage system of FIG. 1 that depicts components of the control system and the energy storage nodes for performance improving suitability analytics.

FIG. 5 is a diagram of the suitability analytics system, according to an embodiment.

FIG. 6 is a flowchart depicting a method for performance improving suitability analytics of an energy storage system, according to an embodiment.

### PARTS LISTING

100 System
10 Energy Storage System
102 Energy System
103 Electrical Application
104 Power Conversion System
105A-N Energy Storage Nodes
106, 106A-N Battery Storage Elements
107 Power Conversion Subsystem
108 Transformer
109 Energy Source
110 Control Subsystem
111A-N Electrical Data
115 Control System
116A-N Battery Data
117A-N Suitability Score
120 Physical Space
125 Power Bus
205 Power Inverter
210 Rectifier
215 DC-DC Converter
300 Enclosure
305, 305A-N Network
311, 351 Network Communication Interface
312, 352 Processor
313, 353 Memory
315A-N Sensors
330A-B Suitability Analytics Control Programming
340A-B Search Protocol Programming
350A-B Diagnostic Analysis Protocol Programming
370A-N Environmental Sensors
375A-N Battery Sensors
500 Suitability Analytics System
505 Operating Data
510 Search Protocol
511A-N Blocks of Operating Data
515 Suitable Input Data
550 Diagnostic Analysis Protocol
555 Analytics Tool Outputs
600 Process Flow

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, transfer functions, and/or circuitry have been described at a relatively high-level, without detail, in order to avoid unnecessarily obscuring aspects of the present teachings.

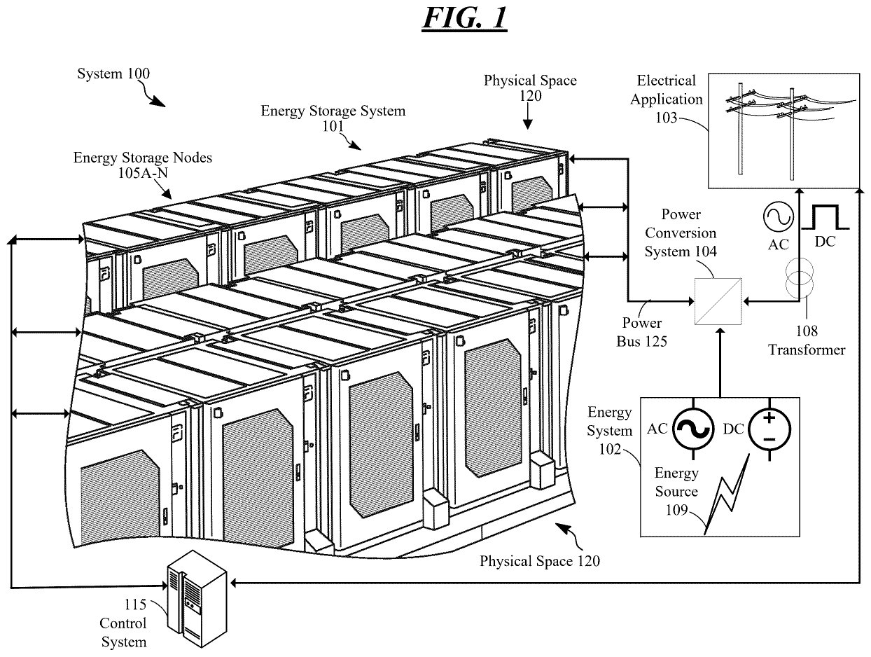

Unless otherwise indicated, any embodiment can be combined with any other embodiment. In particular, FIGS. 1-6 and the associated text are all combinable with each other.

The term “coupled” as used herein refers to any logical, physical, electrical, or optical connection, link or the like by which signals or light produced or supplied by one system element are imparted to another coupled element. Unless described otherwise, coupled elements or devices are not necessarily directly connected to one another and may be separated by intermediate components, elements, or communication media that may modify, manipulate, or carry the light or signals.

The orientations of the system 100, energy storage system 101, energy storage nodes 105A-N, associated components, and/or any complete devices, incorporating battery storage elements 106A-N, such as batteries, such as shown in any of the drawings, are given by way of example only, for illustration and discussion purposes. In operation for a particular energy storage application, an energy storage node 105A-N may be oriented in any other direction suitable to the particular application of the energy storage system 101, for example upright, sideways, or any other orientation. Also, to the extent used herein, any directional term, such as left, right, front, rear, back, end, up, down, upper, lower, top, bottom, and side, are used by way of example only, and are not limiting as to direction or orientation of any energy storage system 101 or energy storage nodes 105A-N; or component of an energy storage system 101 or energy storage nodes 105A-N constructed as otherwise described herein.

Unless otherwise indicated, any multiplicity of components, such as energy storage nodes 105A-N or battery storage elements 106A-N can include any number of said components, including as few as one, and are not limited by the depicted number of components. Unless otherwise indicated, any coupled electrical components can be linked in series or in parallel. In the case of energy storage nodes 105A-N or battery storage elements 106A-N, the components may be linked in series, in parallel, or a combination thereof depending upon a state of a switch or a submodule.

The suitability analytics technologies disclosed herein produce an increased number of analytics tool outputs, and correspondingly an increased number of insights generated from such analytics tools outputs, primarily by reducing the cost and complexity of generating the signals that are needed to feed the analytics tools.

The suitability analytics technologies disclosed herein include the operating data itself (e.g., from an energy storage asset, such as a battery energy storage system or an energy provisioning system, for example), a search algorithm which goes through the operating data and identifies sections of the data suitable for feeding into a diagnostic analysis tool, and the diagnostic analysis tool itself.

Reference now is made in detail to the examples illustrated in the accompanying drawings and discussed below.

FIG. 1 depicts a system 100 that includes an energy storage system 101, energy system 102, and an electrical application 103. For example, the energy storage system 101 can be a battery energy storage system (BESS). The energy storage system 101 is coupled to the energy system 102 and the electrical application 103. Energy storage system 101 can include a power conversion system 104, a plurality of energy storage nodes 105A-N, an optional transformer 108, and a control system 115. Components of the energy storage system 101 can be located at a physical space 120 that is outdoors or indoors, for example, inside of a building, a container, or other structure.

Power conversion system 104 is coupled to the plurality of energy storage nodes 105A-N. The power conversion system 104 is coupled to the energy system 102 and the electrical application 103 to provide a required power flow to the electrical application 103 by discharging the plurality of energy storage nodes 105A-N or the required power flow from the energy system 102 for charging the plurality of energy storage nodes 105A-N. The power conversion system 104 can be coupled to an optional transformer 108. The optional transformer 108 can step up or step down the required power flow to and from the electrical application 103, such as an AC voltage.

Energy system 102 can include any suitable system for producing electrical energy from an energy source 109. Energy system 102 can be a renewable energy system in which the energy source 109 can be replenished. Such a renewable energy source 109 can include solar power, wind power, geothermal power, biomass, and hydroelectric power. For example, the renewable energy system 102 can be implemented as an array of photovoltaic modules. The photovoltaic (PV) modules can include crystalline silicon, amorphous silicon, copper indium gallium selenide (CIGS) thin film, cadmium telluride (CdTe) thin film, and concentrating photovoltaic which uses lenses and curved mirrors to focus sunlight onto small, but highly efficient, multi-junction solar cells. In another example, the energy system 102 can include wind turbines or gas turbines. In some examples, the energy system 102 can be a non-renewable energy system in which the energy source 109 includes a non-renewable energy source, such as a fossil fuel.

Electrical application 103 can include an electrical grid, such as a power grid, or a smaller local load, such as a backup power system, for a facility such as a hospital, manufacturing site, residential home, or other suitable facility. The electrical application 103 may deliver AC or DC power for on-grid or off-grid applications, including commercial, industrial, or residential applications. The electrical application 103 may deliver power to buildings, electric vehicle charging stations, etc., including a variety of electrical loads that consume AC or DC electric power. The electrical application 103 can be a front-of-the-meter system that is owned or operated by a utility company or a behind-the-meter system that directly supplies buildings and homes with electricity.

Energy source 109 can be a renewable energy source, such as solar power and wind power, which can be intermittent and less reliable compared to fossil fuels. To improve resiliency, energy storage system 101 can store energy from the energy system 102 when the production from the energy source 109 is high. Later on, the energy storage system 101 can dispatch the energy to the electrical application 103 when demand is high or production from the energy source 109 is not keeping up with demand. Moreover, events may occur when a connected load or an operating demand load of the electrical application 103 is excessive or there is electrical grid instability, such as during extreme weather. By storing energy from the energy source 109 and then dispatching the energy during such events, the energy storage system 101 can continue to dispatch a required power flow of the electrical application 103.

Energy storage nodes 105A-N include battery storage elements 106A-N. The battery storage elements 106A-N can be: (1) a single battery cell; (2) a cell grouping, including several battery cells in parallel configuration; (3) a battery submodule or module, including several battery cells in parallel and serial configuration; (4) a battery string, including several battery modules in series; (5) a battery bank, including several battery strings in parallel; (6) other known energy storage elements; and/or (7) a combination thereof. For example, the battery storage elements 106A-N can include a plurality of batteries of any existing or future reusable battery technology that can be used in a battery energy storage system (BESS), including, but not limited to, lithium ion or flow batteries, or mechanical storage, such as flywheel energy storage, compressed air energy storage, pumped-storage hydroelectricity, gravitational potential energy, or a hydraulic accumulator, for example.

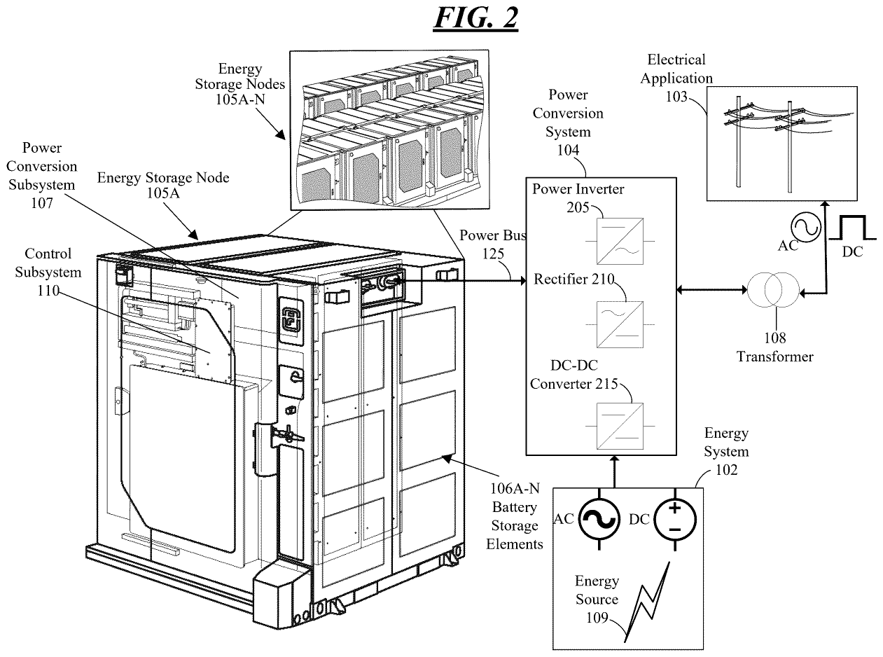

FIG. 2 illustrates a first energy storage node 105A of the plurality of energy storage nodes 105A-N of FIG. 1 coupled to the electrical application 103. Energy storage nodes 105A-N can include a battery storage element 106, a power conversion subsystem 107, and a control subsystem 110, or a combination thereof. Energy storage system 101 can be controlled such that the electrical application 103 is fulfilled while distributing the dispatch of required power flow across the plurality of battery storage elements 106A-N according to awareness of the control system 115 relating to certain battery conditions, including a state of charge, a temperature, and other physical phenomena occurring within the battery storage elements 106A-N.

Power conversion system 104 can include a power inverter 205, a rectifier 210, a DC-DC converter 215, other power conversion elements, or a combination thereof. Power inverter 205 can be configured to convert a DC source, such as from the battery storage elements 106A-N, into an AC waveform. Rectifier 210 can be configured to convert an AC source, such as from the energy system 102 or electrical application 103, into DC for the battery storage elements 106A-N. DC-DC converter 215 can be configured to convert a DC source, such as from the battery storage elements 106A-N, into a different DC source characteristic.

If the energy source 109 is wind power, then the power conversion system 104 can convert the AC electricity produced into DC power for storage in the plurality of energy storage nodes 105A-N via the rectifier 210. If the energy source 109 is solar power, then the power conversion system 104 can convert the DC electricity into a different voltage level via the DC-DC converter 215. The power inverter 205 can convert the required power flow from the energy storage system 101 from DC power into AC power during dispatch to the electrical application 103. For example, the power inverter 205 can be configured to convert power on a power bus 125 for use by the electrical application 103. For example, the power inverter 205 converts DC power stored in the energy storage nodes 105A-N into AC power for consumption by electrical loads of the electrical application 103.

Power conversion subsystem 107 includes similar hardware and software as the more centralized power conversion system 104. Power conversion subsystem 107 is distributed more locally to each of energy storage nodes 105A-N. The control subsystem 110 can be configured for local computation, processing, and control of the battery storage elements 106A-N and the power conversion subsystem 107. The control system 115 can be configured for more centralized computation, processing, and controls of the overall energy storage system 101, energy system 102, electrical application 103, and power conversion system 104. Both the control subsystem 110 and control system 115 can include a single board computer, an application-specific integrated circuit (ASIC), microcontroller, digital signal processor (DSP), field-programmable gate array (FPGA), or a combination thereof.

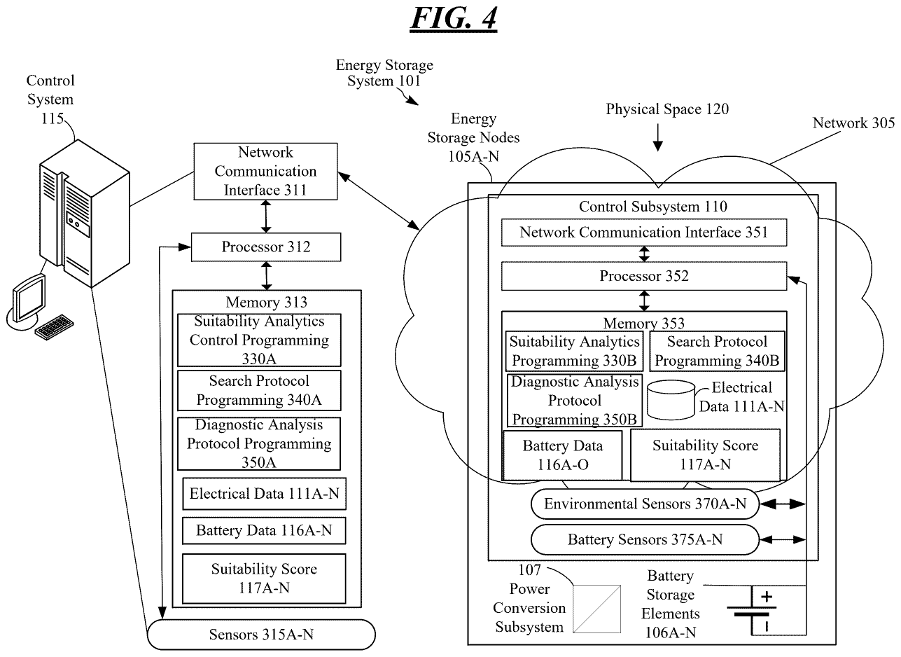

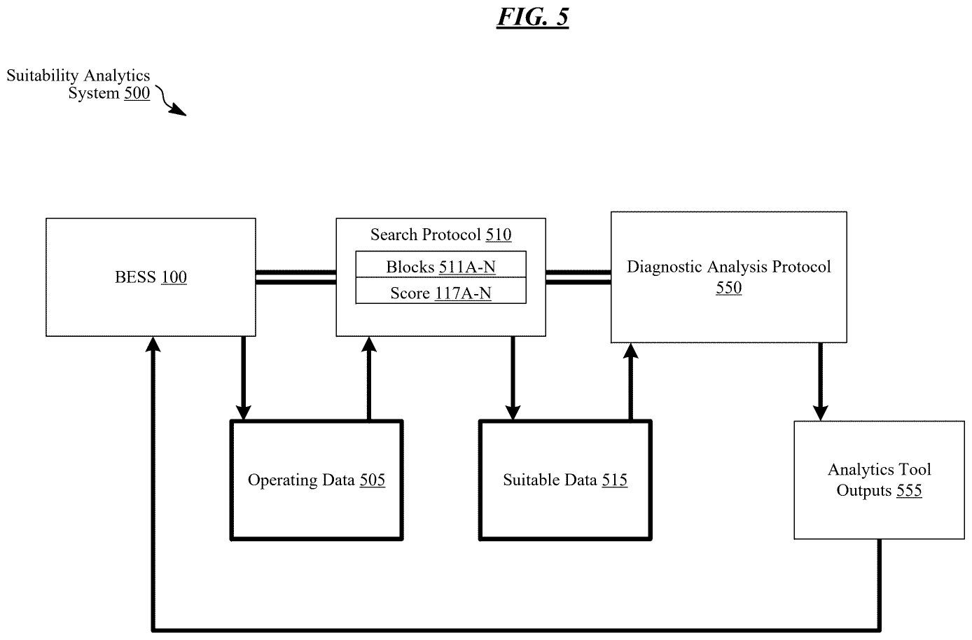

The control system 115 may interface with or include a machine learning model 340, (see FIGS. 4 and 5).

Physical data collection sensors and data logging can be used throughout the energy storage system 101, to collect operational and environmental data from the components of the energy storage system 101, such as the energy storage nodes 105A-N, power conversion systems (PCS) 104, battery management systems (BMSs), apparent power system controllers (APSs), node storage dispatch units (SDUs), core SDUs, and real-time automation controllers (RTACs). The collected data can include, but is not limited to, state of charge (SOC), power, differential voltages, or temperature of the energy storage nodes 105A-N, PCSs, BMSs, APSs, node SDUs, core SDUs, or RTAC.

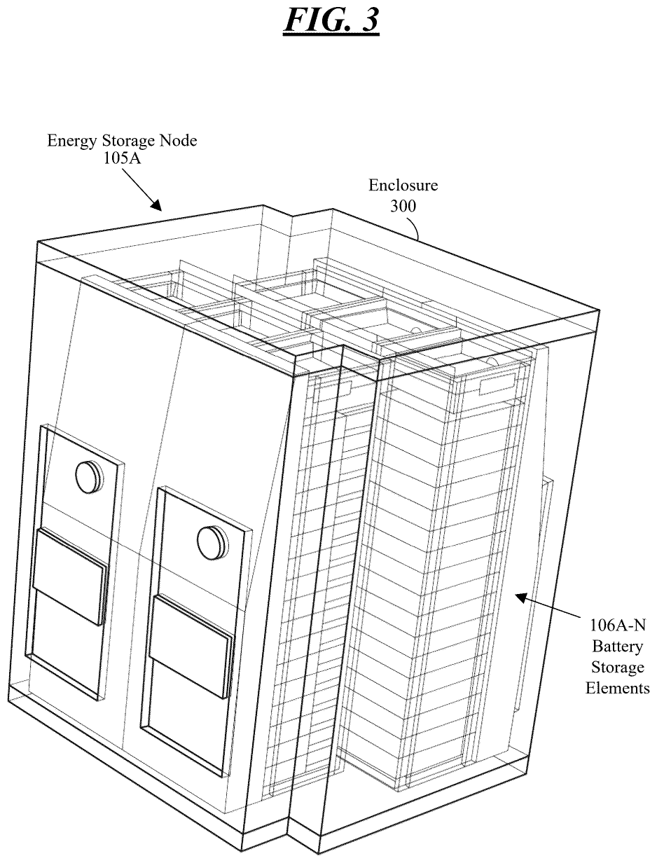

FIG. 3 is a cutaway view of the first energy storage node 105A of the plurality of energy storage nodes 105A-N and shows details of a plurality of battery storage elements 106A-N. As shown, the energy storage node 105A includes an enclosure 300, such as a physical housing to store a plurality of battery storage elements 106A-N. The battery storage elements 106A-N can be a collection of one or more batteries, such as a plurality of battery strings or battery banks, which are organized logically, physically, and electrically.

In the example of FIG. 3, the battery storage elements 106A-N can include battery racks (e.g., six are shown) that hold a respective stack of battery modules (e.g., seventeen are shown). The battery modules can include an array of prismatic, pouch, or cylindrical battery cells that are packaged together to increase voltage, amperage, or both. In some examples, battery modules may include an electric vehicle battery pack, e.g., a collection of lithium-ion battery cells that are packaged together.

The energy storage nodes 105A-N may resemble the features presented in the energy storage system described in International Application No. PCT/US2021/30551, filed on May 4, 2021, titled “Energy Storage System with Removable, Adjustable, and Lightweight Plenums,” the entirety of which is incorporated by reference herein.

FIG. 4 is a high-level functional block diagram of the energy storage system 101 of FIG. 1 that depicts components of the control system 115 and the energy storage nodes 105A-N to search the historical operational data 505 (FIG. 5) of the energy storage system 101 and determine suitable input data 515 (FIG. 5) for performance improving suitability analytics by creating summary parameters for the blocks of historical operating data 505, evaluating each of the summary parameters against selection criteria, and feeding selected operating data as input suitable input data 515 to a diagnostic analysis protocol for the energy storage system based on the evaluation of the summary parameters against the selection criteria.

As shown in FIG. 4, the plurality of energy storage nodes 105A-N include a battery storage element 106A-N, a power conversion subsystem 107, and a control subsystem 110 configured to receive historical operating data 505 from the battery storage element 106A-N, the power conversion subsystem 107, or a combination thereof. The historical operating data 505 can include, but is not limited to, operating data from the plurality of energy storage nodes 105A-N related to actual dispatch of one or more of the energy storage nodes 105A-N of the energy storage system 101.

The summary parameters for the blocks of historical operating data 505 of the energy storage system 101 can include, but are not limited to, operating conditions, such as a value of the state of charge (“SoC”) of the plurality of energy storage nodes 105A-N over time, temperatures of the plurality of energy storage nodes 105A-N, power levels of the plurality of energy storage nodes 105A-N, voltages, currents, or ranges of temperatures, power levels, voltages, and currents of the plurality of energy storage nodes 105A-N, for example. The summary parameters for the blocks of historical operating data 505 of the energy storage system 101 can also include, but are not limited to, operational data or electrical data 111A-N, such as current, voltage, power, charge or discharge commands, power pulse patterns during charging or discharging (e.g., activity pattern), apparent power or real time power (e.g., activity pattern) from the battery storage element 106A-N, the power conversion subsystem 107, or a combination thereof, and battery data 116A-N, such as battery voltage, battery current, battery temperature, battery state of charge (SOC), or other physical phenomena occurring within the battery storage elements 106A-N, and/or environmental data, in particular voltage, current, temperature, or state of charge from the components of the battery energy storage system, such as the power input and output of PCSs or battery management systems (BMSs), which, along with the PCSs, communicate with apparent power system controllers (APSs), full operating system (FOS) control signals, as well as feedback and statuses from a battery management system (BMS), the battery storage element 106A-N, power conversion system (PCS) 104, and meter subsystems. The APSs and the BMSs communicate with node storage dispatch units (SDUs). Node SDUs interface with and monitor the connected BMSs, PCSs and other hardware to higher level controls. The electrical data 111A-N can also include at least one of current and voltage or power output of the power conversion system 104.

The control system 115, energy storage nodes 105A-N, electrical application 103, and other components of the system 100 can be in communication over a network 305 or one or more networks 305A-N. The networks 305A-N can be a local area network 305A, wide area network 305B, or a combination thereof. For example, the control system 115 can be coupled via a local area network 305A to the energy storage nodes 105A-N and the electrical application 103. Alternative or additionally, the control system 115 can be coupled via a wide area network 305B to the energy storage nodes 105A-N and electrical application 103. Or the control system 115 can be coupled via a combination of networks 305A-N, such as via a local area network 305A to components of the energy storage system 101, including the energy storage nodes 105A-N, and coupled via a wide area network 305B to the electrical application 103.

Control system 115 includes a network communication interface 311 configured for wired or wireless communication over the network 305. The control system 115 further includes a memory 313, and a processor 312 coupled to the network communication interface 311 and the memory 313. As shown in FIG. 4, the memory 313 of the control system 115 is configured to store a suitability analytics control programming 330A, a search protocol programming 340A, a diagnostic analysis protocol programming 350A, electrical data 111A-N, and battery data 116A-N, for example. The control system 115 can also include sensors 315A-N coupled to the processor 312 to detect or monitor various system parameters, such as power, temperature, voltage, current, resistance, and/or impedance, for example. For example, the sensors 315A-N can be coupled to the power bus 125.

Control system 115 is configured to store, e.g., in memory 313, selection criteria, such as suitability score 117A-N, for example, for each of the summary parameters (e.g., battery data 116A-N, electrical data 111A-N) from the battery storage element 106A-N, the power conversion subsystem 107, or a combination thereof. Based on the suitability score 117A-N for each of the summary parameters, the control system 115 can send suitable input data 515 as input to the diagnostic analysis protocol 550 (FIG. 5), as described further below. In the context of the present disclosure, the suitability score 117A-N can be based on relative weighting of the summary parameters or collection of conditions that must be met for the operating data 505 of the energy storage system 101 to be suitable for analysis. The suitability score 117A-N for each of the summary parameters can be a number of any range of numbers. For example, a higher suitability score 117A-N for each of the summary parameters can indicate better suitability for analysis of the operating data 505 of the energy storage system 101.

Turning back to FIG. 4, energy storage nodes 105A-N include a control subsystem 110, battery storage elements 106A-N, and a power conversion subsystem 107. Control subsystem 110 of the energy storage nodes 105A-N includes a network communication interface 351 configured for wired or wireless communication over the network 305. The control subsystem 110 further includes a memory 353, and a processor 352 coupled to the network communication interface 351 and the memory 353. As shown, the memory 353 of the control subsystem 110 can be configured to store a suitability analytics control programming 330B, a search protocol programming 340B, a diagnostic analysis protocol programming 350B, battery data 116A-N, and electrical data 111A-N from the battery storage elements 106A-N, the power conversion subsystem 107, or a combination thereof, and suitability score 117A-N for each of the summary parameters (e.g., battery data 116A-N, electrical data 111A-N) from the battery storage element 106A-N, the power conversion subsystem 107, or a combination thereof.

The control subsystem 110 can further include environmental sensors 370A-N coupled to the processor 352. Environmental sensors 370A-N can measure, for example, humidity and temperature inside of an enclosure 300 (see FIG. 3) of the energy storage nodes 105A-N.

A suitability analytics system 500 (see FIG. 5) may be fully or partially embedded in, or receive operating data 505 (see FIG. 5) from, the components of the energy storage nodes 105A-N, such as the battery cells, battery modules, battery strings, or battery bank, for example.

FIG. 5 is a diagram of the suitability analytics system 500. The suitability analytics system 500 implements a method for finding a pattern in the operating data 505 suitable for feeding an analytic tool (e.g., a tool implementing a diagnostic analysis protocol 550)—that is, looking across existing operating data 505 that is stored and finding cases where the operating data 505 fits what is needed by the diagnostic analysis protocol 550. The suitability analytics system 500 includes a search protocol 510 that characterizes blocks 511A-N of historical operating data 505 and creates summary parameters for the blocks 511A-N of operating data 505.

The summary parameters can describe operating conditions within the blocks of historical operating data 505 from the plurality of energy storage nodes 105A-N or characteristics in either the time domain or the frequency domain. For example, the summary parameters can describe the operating condition within the block 511A (e.g., high SoC over time, sequence, duration of time at a certain condition, or rate of change over time of the operating conditions of the plurality of energy storage nodes 105A-N between charging and discharging) or characteristics that are not in the time domain, such as a parametric view of the electrical frequency domain indicating how rapidly the plurality of energy storage nodes 105A-N switch between charging and discharging, for example. Parametric view of the electrical frequency domain can include, but is not limited to, techniques, such as Fourier transform, power spectral density, and transfer functions, for example.

Turning back to FIG. 5, once the blocks 511A-N of historical operating data 505 have been parameterized across a breadth of characteristics and conditions, a suitability score 117A-N is generated for the operating data 505 using these parameters for analytics of interest. More generally, a procedure is run to find the best match of the operating data 505 for the desired diagnostic analysis protocol 550. Based on the suitability score 117A-N, the selected operating data 505 is sent as suitable input data 515 to the diagnostic analysis protocol 550. Additionally, the parameters for the identified historical block 511A can also be fed as inputs (e.g., as a part of suitable input data 515) into the diagnostic analysis protocol 550. In this way, the diagnostic analysis protocol 550 can account for the characteristics of the suitable input data 515 it is receiving and make incremental adjustments to its operation, to the extent valuable to do so.

In an alternative case, history of operating data 505 (e.g., historical operating data) can be used to fine-tune or even design a diagnostic analysis protocol 550 (e.g., a model creating the model) in cases where multiple options or approaches exist to achieve the desired outcome of a diagnostic.

As a further alternative to diagnostic design, as the model is trained of a system of assets (e.g., one or more energy storage nodes 105A-N) of the energy storage system 101 (e.g., ISO dispatch), a forecasted dispatch or expected dispatch may be considered instead of actual dispatch of a given asset of the energy storage system 101. For example, an actual dispatch can include the actual use of energy from of a given asset of the energy storage system 101 based on actual demand from a connected load, or an operating demand load or required power flow of the electrical application 103. A forecasted dispatch or expected dispatch can include predictions of future load demand based on weather, region, or historical observed energy use, for example.

The output 555 (FIG. 5) from the diagnostic analysis protocol 550 can be used to control the operation of the energy storage system 101 or for maintenance, service, or diagnostics of the energy storage system 101. Examples of control of the operation of the energy storage system 101 can include, but are not limited to, operating the energy storage system 101 in a different way, e.g., once the SoC of the battery system is known, to turn off, change the temperature, reduce operating power, or limit the SoC range.

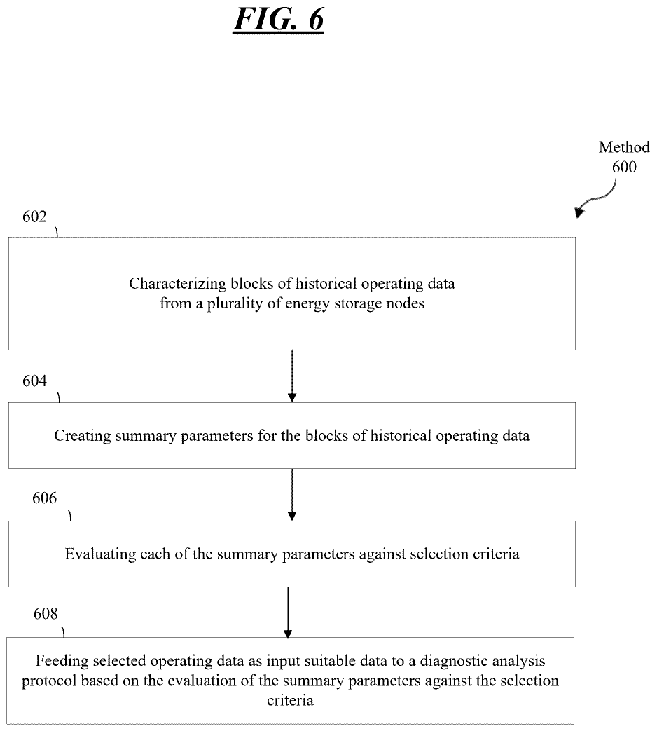

FIG. 6 is a flowchart of a method 600 for performance improving suitability analytics of an energy storage system 101, according to an embodiment.

Beginning in step 602, the method 600 includes characterizing blocks of historical operating data 505 (FIG. 5) from a plurality of energy storage nodes 105A-N of an energy storage system 101 (FIGS. 1 and 2). The energy storage nodes 105A-N can include a battery storage element 106, a power conversion subsystem 107, and a control subsystem 110 to receive the battery data 111A-N from the battery storage element 106, the power conversion subsystem 107, or a combination thereof.

Continuing to step 604, the method 600 further includes creating summary parameters for the blocks of historical operating data 505. The summary parameters can include, but are not limited to, operating conditions, such as a value of the state of charge (“SoC”) of the plurality of energy storage nodes 105A-N over time, temperatures of the plurality of energy storage nodes 105A-N, power levels of the plurality of energy storage nodes 105A-N, voltages, currents, or ranges of temperatures, power levels, voltages, and currents of the plurality of energy storage nodes 105A-N.

Continuing to step 606, the method 600 further includes evaluating each of the summary parameters against selection criteria. The selection criteria can include, but is not limited to, a suitability score 117A-N for each of the summary parameters (e.g., battery data 116A-N, electrical data 111A-N) from the battery storage element 106A-N, the power conversion subsystem 107, or a combination thereof.

Continuing to step 608, the method 600 further includes feeding selected operating data 515 (FIG. 5) as suitable input data to a diagnostic analysis protocol 550 for the energy storage system 101 based on the evaluation of the summary parameters against the selection criteria.

Although not shown in FIG. 6, the method 600 can further include a step of finding a pattern in the historical operating data 505 from the plurality of energy storage nodes 105A-N that is suitable for feeding an analytic tool.

Although not shown in FIG. 6, the method 600 can further include a step of using the historical operating data 505 from the plurality of energy storage nodes 105A-N to fine-tune or design the diagnostic analysis protocol 550.

Although not shown in FIG. 6, the method 600 can further include a step of using the output 555 (FIG. 5) from the diagnostic analysis protocol 550 to control an operation of the energy storage system 101 or for maintenance, service, or diagnostics of the energy storage system 101. Examples of control of the operation of the energy storage system 101 can include, but are not limited to, operating the energy storage system 101 in a different way, e.g., once the SoC of the battery system is known, turn off, change the temperature, reduce operating power, or limit the SoC range.

In the examples above, the energy storage system 101, the energy system 102, energy application 103, power conversion system 104, energy storage nodes 105A-N, control subsystem 110, control system 115, etc. can each include a processor. As used herein, a processor 312, 352 is a hardware circuit having elements structured and arranged to perform one or more processing functions, typically various data processing functions. Although discrete logic components could be used, the examples utilize components forming a programmable central processing unit (CPU). A processor 312, 352 for example includes or is part of one or more integrated circuit (IC) chips incorporating the electronic elements to perform the functions of the CPU. The processors 312, 352 for example, may be based on any known or available microprocessor architecture, such as a Reduced Instruction Set Computing (RISC) using an ARM architecture. Of course, other processor circuitry may be used to form the CPU or processor hardware in. The illustrated examples of the processors 312, 352 can include one microprocessor or a multi-processor architecture. A digital signal processor (DSP) or field-programmable gate array (FPGA) could be suitable replacements for the processors 312, 352, but may consume more power with added complexity.

The applicable processor 312, 352 executes programming or instructions to configure the energy system 102, energy application 103, power conversion system 104, energy storage nodes 105A-N, control subsystem 110, control system 115, etc. to perform various operations. For example, such operations may include various general operations (e.g., a clock function, recording and logging operational status and/or failure information) as well as various system-specific operations functions. Although a processor 312, 352 may be configured by use of hardwired logic, typical processors are general processing circuits configured by execution of programming, e.g., instructions and any associated setting data from the memories 313, 353 shown or from other included storage media and/or received from remote storage media.

In the examples above, the energy system 102, energy application 103, power conversion system 104, energy storage nodes 105A-N, control subsystem 110, control system 115, etc. each include a memory. The memory 313, 353 may include a flash memory (non-volatile or persistent storage), a read-only memory (ROM), and a random access memory (RAM) (volatile storage). The RAM serves as short term storage for instructions and data being handled by the processors 312, 352 e.g., as a working data processing memory. The flash memory typically provides longer term storage.

Of course, other storage devices or configurations may be added to or substituted for those in the example. Such other storage devices may be implemented using any type of storage medium having computer or processor readable instructions or programming stored therein and may include, for example, any or all of the tangible memory of the computers, processors or the like, or associated modules.

Hence, a machine-readable medium or a computer-readable medium may take many forms of tangible storage medium. Non-volatile storage media include, for example, optical or magnetic disks, such as any of the storage devices in any computer(s) or the like, such as may be used to implement the client device, media gateway, transcoder, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards, paper tape, any other physical storage medium with patterns of holes, a RAM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

According to exemplary embodiments of the present disclosure the one or more processors and control circuits can include one or more of any known general purpose processor or integrated circuit such as a central processing unit (CPU), microprocessor, field programmable gate array (FPGA), Application Specific Integrated Circuit (ASIC), Digital Signal Processor (DSP), or other suitable programmable processing or computing device or circuit as desired that is specially programmed to perform operations for achieving the results of the exemplar embodiments described herein. The processor(s) can be configured to include and perform features of the exemplary embodiments of the present disclosure, such as the suitability analytics control programming 330A-B, the search protocol programming 340A-B, and the diagnostic analysis protocol 350A-B, for example. The features can be performed through program code encoded or recorded on the processor(s), or stored in a non-volatile memory device, such as Read-Only Memory (ROM), erasable programmable read-only memory (EPROM), or other suitable memory device or circuit as desired. Accordingly, such computer programs can represent controllers of the computing device.

In another exemplary embodiment, the program code, such as the suitability analytics control programming 330A-B, the search protocol programming 340A-B, and the diagnostic analysis protocol programming 350A-B can be provided in a computer program product having a non-transitory computer readable medium, such as Magnetic Storage Media (e.g. hard disks, floppy discs, or magnetic tape), optical media (e.g., any type of compact disc (CD), or any type of digital video disc (DVD), or other compatible non-volatile memory device as desired) and downloaded to the processor(s) for execution as desired, when the non-transitory computer readable medium is placed in communicable contact with the processor(s).

The one or more processors 312, 352 can be included in a computing system that is configured with components such as memory, a hard drive, an input/output (I/O) interface, a communication interface, a display and any other suitable component as desired. The exemplary computing device can also include a communications interface. The communications interface can be configured to allow software and data to be transferred between the computing device and external devices. Exemplary communications interfaces can include a modem, a network interface (e.g., an Ethernet card), a communications port, a PCMCIA slot and card, or any other suitable network communication interface as desired. Software and data transferred via the communications interface can be in the form of signals, which can be electronic, electromagnetic, optical, or other signals as will be apparent to persons having skill in the relevant art. The signals can travel via a communications path, which can be configured to carry the signals and can be implemented using wire, cable, fiber optics, a phone line, a cellular phone link, a radio frequency link, or any other suitable communication link as desired.

Where the present disclosure is implemented using programming or software, including but not limited to the suitability analytics control programming 330A, the search protocol programming 340A, and the diagnostic analysis protocol programming 350A, for example, the programming or software can be stored in a computer program product or non-transitory computer readable medium and loaded into the computing device using a removable storage drive or communications interface. In an exemplary embodiment, any computing device, such as control system 115 and control subsystem 110, disclosed herein can also include a display interface that outputs display signals to a display unit, e.g., LCD screen, plasma screen, LED screen, DLP screen, CRT screen, or any other suitable graphical interface as desired.

It will be understood that the terms and expressions used herein have the ordinary meaning as is accorded to such terms and expressions with respect to their corresponding respective areas of inquiry and study except where specific meanings have otherwise been set forth herein. Relational terms such as first and second, or evident and alternative, and the like may be used solely to distinguish one entity or action from another without necessarily requiring or implying any actual such relationship or order between such entities or actions. The terms “comprises,” “comprising,” “includes,” “including,” or any other variation thereof, are intended to cover a non-exclusive inclusion, such that a process, method, article, or apparatus that comprises or includes a list of elements or steps does not include only those elements or steps but may include other elements or steps not expressly listed or inherent to such process, method, article, or apparatus. An element preceded by “a” or “an” does not, without further constraints, preclude the existence of additional identical elements in the process, method, article, or apparatus that comprises the element.

Unless otherwise stated, any and all measurements, values, ratings, positions, magnitudes, sizes, angles, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as ±5% or as much as ±10% from the stated amount. The terms “approximately” and “substantially” mean that the parameter value or the like varies up to ±10% from the stated amount or position.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus, the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present concepts.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

1. A system, comprising:
an energy storage system including a plurality of energy storage nodes, wherein each of the plurality of energy storage nodes includes a battery storage element;
a memory;
a processor coupled to the memory and the plurality of energy storage nodes;
programming in the memory, wherein execution of the programming by the processor configures the system to:
characterize blocks of historical operating data from the plurality of energy storage nodes;
create summary parameters for the blocks of historical operating data;
evaluate each of the summary parameters against selection criteria; and
feed selected operating data as suitable input data to a diagnostic analysis protocol for the energy storage system based on the evaluation of the summary parameters against the selection criteria.

2. The system of claim 1, wherein the summary parameters comprise operating conditions, and wherein the operating conditions comprise at least one of a value of state of charge (“SoC”) of the plurality of energy storage nodes over time, temperatures of the plurality of energy storage nodes, power levels of the plurality of energy storage nodes, voltages, currents, or ranges of temperatures, power levels, voltages, and currents of the plurality of energy storage nodes.

3. The system of claim 1, wherein the summary parameters comprise operating conditions within the blocks of historical operating data from the plurality of energy storage nodes or characteristics in either of a time domain or a frequency domain.

4. The system of claim 3, wherein the characteristics in the time domain comprise a sequence, duration of time at a certain condition, or rate of change over time of the operating conditions of the plurality of energy storage nodes between charging and discharging.

5. The system of claim 3, wherein the characteristics in the frequency domain comprise a parametric view of the frequency domain indicating how rapidly the plurality of energy storage nodes switch between charging and discharging.

6. The energy storage system of claim 1, wherein execution of the programming by the processor configures the system to feed parameters of an identified historical block as part of the suitable input data into the diagnostic analysis protocol.

7. The energy storage system of claim 1, wherein execution of the programming by the processor configures the system to use the historical operating data from the plurality of energy storage nodes to fine-tune or design the diagnostic analysis protocol.

8. The energy storage system of claim 7, wherein the historical operating data from the plurality of energy storage nodes comprises an actual dispatch of one or more of the energy storage nodes of the energy storage system.

9. The energy storage system of claim 7, wherein execution of the programming by the processor configures the system to characterize a forecasted dispatch of one or more energy storage nodes of the energy storage system.

10. The energy storage system of claim 1, wherein execution of the programming by the processor configures the system to use output from the diagnostic analysis protocol to control an operation of the energy storage system or for maintenance, service, or diagnostics of the energy storage system.

11. A method, comprising:
characterizing blocks of historical operating data from a plurality of energy storage nodes of an energy storage system;
creating summary parameters for the blocks of historical operating data;
evaluating each of the summary parameters against selection criteria; and
feeding selected operating data as suitable input data to a diagnostic analysis protocol for the energy storage system based on the evaluation of the summary parameters against the selection criteria.

12. The method of claim 11, further comprising finding a pattern in the historical operating data from the plurality of energy storage nodes that is suitable for feeding an analytic tool.

13. The method of claim 11, wherein the summary parameters comprise operating conditions, and wherein the operating conditions comprise at least one of a value of state of charge (“SoC”) of the plurality of energy storage nodes over time, temperatures of the plurality of energy storage nodes, power levels of the plurality of energy storage nodes, voltages, currents, or ranges of temperatures, power levels, voltages, and currents of the plurality of energy storage nodes.

14. The method of claim 11, wherein the summary parameters comprise operating conditions within the blocks of historical operating data from the plurality of energy storage nodes or characteristics in either of a time domain or a frequency domain.

15. The method of claim 14, wherein the characteristics in the frequency domain comprise a parametric view of the frequency domain indicating how rapidly the plurality of energy storage nodes switch between charging and discharging.

16. The method of claim 11, further comprising feeding parameters of an identified historical block as part of the suitable input data into the diagnostic analysis protocol.

17. The method of claim 11, further comprising using the historical operating data from the plurality of energy storage nodes to fine-tune or design the diagnostic analysis protocol.

18. The method of claim 11, wherein the historical operating data from the plurality of energy storage nodes comprises an actual dispatch of one or more of the energy storage nodes of the energy storage system.

19. The method of claim 18, further comprising characterizing a forecasted dispatch of one more of the energy storage nodes of the energy storage system.

20. The method of claim 11, further comprising using output from the diagnostic analysis protocol to control an operation of the energy storage system or for maintenance, service, or diagnostics of the energy storage system.

21. (canceled)
